(19) United States
(12) Patent Application Publication
(10) Pub. No.: US 2018/0315939 A1
(43) Pub. Date: Nov. 1, 2018

(54) FABRICATION METHOD OF A LARGE AREA PEROVSKITE SOLAR CELL

(71) Applicants: Research & Business Foundation Sungkyunkwan University, Suwon-si (KR); Global Frontier Center for Multiscale Energy Systems, Seoul (KR)

(72) Inventors: Hyun Suk JUNG, Seoul (KR); Byeong Jo KIM, Incheon (KR); Dong Geon LEE, Suwon-si (KR); SangMyeong LEE, Suwon-si (KR); Gi Joo BANG, Suwon-si (KR); Min-Cheol KIM, Seoul (KR); Ji Hyun BAEK, Suwon-si (KR)

(73) Assignees: Research & Business Foundation Sungkyunkwan University, Suwon-si (KR); Global Frontier Center for Multiscale Energy Systems, Seoul (KR)

(21) Appl. No.: 15/954,762

(22) Filed: Apr. 17, 2018

(30) Foreign Application Priority Data
Apr. 28, 2017 (KR) 10-2017-0055341

(51) Int. Cl. H01L 51/42; H01L 51/44; H01L 51/50; H01L 51/00; H01L 31/0264

(52) U.S. Cl. CPC H01L 51/4206; H01L 51/442; H01L 51/5056; H01L 51/5072; H01L 2031/0344; H01L 51/0052; H01L 51/0062; H01L 51/0007; H01L 31/0264; H01L 51/0096

(57) ABSTRACT

The present disclosure relates to a method of fabricating a perovskite solar cell, including: forming an electron transport layer on a substrate; forming a light absorbing layer containing a perovskite material on the electron transport layer; forming a hole transport layer on the light absorbing layer; and forming an electrode on the hole transport layer. Herein, the forming of the light absorbing layer is performed by impregnating the substrate on which the electron transport layer is formed in a nonpolar solvent and performing a heat treatment thereto.

### CROSS-REFERENCE TO RELATED APPLICATION

This application claims the benefit of Korean Patent Application No. 10-2017-0055341 filed on Apr. 28, 2017, the disclosures of which are incorporated herein by reference.

### TECHNICAL FIELD

The present disclosure relates to a method of fabricating a perovskite solar cell and a perovskite solar cell fabricated thereby.

### BACKGROUND

Perovskite solar cells are currently considered as the most promising next-generation energy source due to applicability of a solution process to a photoactive layer and possibility of manufacturing a device with high efficiency, and have marked tremendous progress despite a short period of research.

Accordingly, various perovskite solar cells are being developed as shown in Korean Patent No. 10-1717430.

Conventionally, such a perovskite solar cell has been manufactured by dropping a nonpolar solvent during spin-coating and thus forming a mesophase of a perovskite light absorbing layer and then performing a heat treatment and thus forming a uniform thin film. The conventional method has greatly contributed to the efficiency improvement of perovskite solar cells. However, in the case where the size of a substrate is increased, it is difficult to coat a thin film having a uniform thickness on the substrate by the spin coating process. Therefore, the spin coating process is not suitable for large-area process. Further, the conventionally used nonpolar solvents such as toluene and chlorobenzene have a property of dissolving dimethyl sulfoxide (DMSO) and are highly reactive. Therefore, when applied to a bath process, such a nonpolar solvent cannot uniformly form a perovskite mesophase containing DMSO on the substrate. Accordingly, there is a need for the development of a method of fabricating a perovskite solar cell in which a perovskite mesophase is uniformly formed by solving this problem.

### SUMMARY

In view of the foregoing, the present disclosure provides a method of fabricating a perovskite solar cell.

Further, the present disclosure provides a perovskite solar cell fabricated by the above-described fabrication method.

However, problems to be solved by the present disclosure are not limited to the above-described problems. There may be other problems to be solved by the present disclosure.

According to a first aspect of the present disclosure, there is provided a method of fabricating a perovskite solar cell, including: forming an electron transport layer on a substrate; forming a light absorbing layer containing a perovskite material on the electron transport layer; forming a hole transport layer on the light absorbing layer; and forming an electrode on the hole transport layer. Herein, the forming of the light absorbing layer is performed by impregnating the substrate on which the electron transport layer is formed in a nonpolar solvent and performing a heat treatment thereto.

According to an embodiment of the present disclosure, the nonpolar solvent may form a perovskite mesophase, but may not be limited thereto. According to an embodiment of the present disclosure, the nonpolar solvent may be selected from the group consisting of chlorobenzene, 1,2-dichlorobenzene, 1,3-dichlorobenzene, chloronaphthalene, and mixed solvents thereof, but may not be limited thereto.

According to an embodiment of the present disclosure, the heat treatment may be performed at from 100° C. to 200° C., but may not be limited thereto.

According to an embodiment of the present disclosure, the electron transport layer may include an oxide of a metal selected from the group consisting of titanium, tin, zinc, tungsten, zirconium, gallium, indium, yttrium, niobium, tantalum, vanadium, and combinations thereof, but may not be limited thereto.

According to an embodiment of the present disclosure, the oxide of the metal may be selected from the group consisting of titanium dioxide (TiO₂), tin oxide (SnO₂), titanium (II) chloride (TiCl₂), zinc oxide (ZnO), copper (II) oxide (CuO), nickel (II) oxide (NiO), cobalt (II) oxide (CoO), indium oxide (In₂O₃), tungsten oxide (WO₃), magnesium oxide (MgO), calcium oxide (CaO), lanthanum oxide (La₂O₃), neodymium oxide (Nd₂O₃), yttrium oxide (Y₂O₃), cerium oxide (CeO₂), lead oxide (PbO), zirconium oxide (ZrO₂), iron oxide (Fe₂O₃), bismuth oxide (Bi₂O₃), vanadium pentoxide (V₂O₅), vanadium oxide (VO₂), niobium pentoxide (Nb₂O₅), cobalt(II,III) oxide (CO₃O₄), aluminum oxide (Al₂O₃), and combinations thereof, but may not be limited thereto.

According to an embodiment of the present disclosure, the perovskite material may include a compound represented by the following Chemical Formula 1, but may not be limited thereto.

RMX₃ [Chemical Formula 1]

In Chemical Formula 1, R includes an organic cation or an alkaline metal cation, or a mixed cation of the organic cation and the alkaline metal cation, M includes a metal cation selected from the group consisting of Cu²⁺, Ni²⁺, Co₂₊, Fe²⁺, Mn²⁺, Cr²⁺, Pd²⁺, Cd²⁺, Yb²⁺, Pb²⁺, Sn²⁺, Ge²⁺, and combinations thereof, and X is an anion.

According to an embodiment of the present disclosure, in Chemical Formula 1, R is a monovalent organic ammonium ion represented by (R¹R²R³R⁴N)⁺, and R¹ to R⁴ may include, each independently, a linear or branched alkyl group having 1 to 24 carbon atoms, a cycloalkyl group having 3 to 20 carbon atoms, an aryl group having 6 to 20 carbon atoms, and combinations thereof, but may not be limited thereto.

According to an embodiment of the present disclosure, in Chemical Formula 1, X may include a halide anion or a chalcogenide anion, but may not be limited thereto.

According to an embodiment of the present disclosure, the hole transport layer may contain a hole transport material selected from the group consisting of 2,2′,7,7′-tetrakis(diphenylamino)-9,9′-spirobifluorene (Spiro-MeOTAD), 4-tert-Butylpyridine (tBP), bis(trifluoromethane)sulfonimide lithium salt (Li-TFSI), poly-hexylthiophene (P3HT), poly[2-methoxy-5-(2-ethylhexyloxy)-1,4-phenylenevinylene] (MEHPPV), poly[2,5-bis(2-decyl dodecyl)pyrrolo[3,4-c]pyrrole-1,4(2H,5H)-dione-(E)-1,2-di(2,2′-bithiophen-5-yl)ethene (PDPPDBTE), and combinations thereof, but may not be limited thereto.

According to an embodiment of the present disclosure, the substrate may include a glass substrate or plastic substrate containing a material selected from the group consisting of indium tin oxide (ITO), fluorine tin oxide (FTO), ZnO—Ga₂O₃, ZnO—Al₂O₃, tin-based oxide, zinc oxide, glass and combinations thereof, but may not be limited thereto.

According to an embodiment of the present disclosure, the plastic substrate may contain a polymer selected from the group consisting of polyethyleneterephthalate, poly(ethylenenaphthalate) (PEN), polycarbonate, polypropylene, polyimide, cellulose triacetate, and combinations thereof, but may not be limited thereto.

According to an embodiment of the present disclosure, the electrode layer may contain a member selected from the group consisting of Pt, Au, Ni, Cu, Ag, In, Ru, Pd, Rh, Ir, Os, C, conductive polymers, and combinations thereof, but may not be limited thereto.

According to an embodiment of the present disclosure, the electrode layer may be formed to a thickness of from 30 nm to 100 nm on the hole transport layer, but may not be limited thereto.

According to a second aspect of the present disclosure, there is provided a perovskite solar cell fabricated by the fabrication method.

The above-described embodiments are provided by way of illustration only and should not be construed as liming the present disclosure. Besides the above-described embodiments, there may be additional embodiments described in the accompanying drawings and the detailed description.

According to the above-described aspects of the present disclosure, it is possible to provide a method of fabricating a perovskite solar cell in which a perovskite light absorbing layer is impregnated in a nonpolar solvent and thus formed to a uniform thickness.

According to a conventional method of fabricating a perovskite solar cell, in the case where a conventional spin coating process in which a nonpolar solvent is dropped to form a mesophase of a perovskite light absorbing layer and a heat treatment is performed to form a thin film is applied to a large-area process, as the size of a substrate is increased, a thin film having a non-uniform thickness is coated on the substrate. Further, the conventionally used nonpolar solvents such as toluene and chlorobenzene have a property of dissolving dimethyl sulfoxide (DMSO) and are highly reactive. Therefore, when applied to a bath process, such a nonpolar solvent cannot uniformly form a perovskite mesophase containing DMSO.

Meanwhile, in the method of fabricating a perovskite solar cell according to the present disclosure, a spin coating process which is not suitable to form a large-area perovskite light absorbing layer is complemented by a bath process and impregnation is performed using a nonpolar solvent having low reactivity to uniformly form a perovskite mesophase on a substrate, followed by a heat treatment.

The nonpolar solvent having low reactivity slowly washes DMF or DMSO and thus slowly forms crystals. Therefore, it is possible to form a perovskite mesophase having a uniform thickness.

Accordingly, a large-area perovskite solar cell device and a module can be fabricated by the method of fabricating a perovskite solar cell of the present disclosure which can also be applied to a roll-to-roll process. Therefore, it can also be used in a commercialization stage.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 shows a schematic diagram illustrating a conventional method of fabricating a perovskite solar cell and an image showing the uniformity of a perovskite light absorbing layer depending on the reactivity of a nonpolar solvent.

FIG. 2 is a schematic diagram illustrating a bath process for fabricating a perovskite solar cell according to an embodiment of the present disclosure.

FIG. 3A-FIG. 3B are schematic diagrams provided to explain a difference in uniformity of a perovskite light absorbing layer formed depending on the reactivity of a nonpolar solvent.

FIG. 4A-FIG. 4B shows SEM (scanning electron microscopy) images of a cross-section of a perovskite light absorbing layer according to an example of the present disclosure.

FIG. 5A and FIG. 5B show a SEM image and J-V curve data, respectively, of a perovskite solar cell device according to an example of the present disclosure.

### DETAILED DESCRIPTION

Hereinafter, embodiments of the present disclosure will be described in detail with reference to the accompanying drawings so that the present disclosure may be readily implemented by those skilled in the art.

However, it is to be noted that the present disclosure is not limited to the embodiments but can be embodied in various other ways. In drawings, parts irrelevant to the description are omitted for the simplicity of explanation, and like reference numerals denote like parts through the whole document.

Through the whole document, the term “connected to” or “coupled to” that is used to designate a connection or coupling of one element to another element includes both a case that an element is “directly connected or coupled to” another element and a case that an element is “electronically connected or coupled to” another element via still another element.

Through the whole document, the terms “on”, “above”, “on an upper end”, “below”, “under”, and “on a lower end” that are used to designate a position of one element with respect to another element include both a case that the one element is adjacent to the other element and a case that any other element exists between these two elements.

Further, through the whole document, the term “comprises or includes” and/or “comprising or including” used in the document means that one or more other components, steps, operation and/or existence or addition of elements are not excluded in addition to the described components, steps, operation and/or elements unless context dictates otherwise.

Through the whole document, the term “about or approximately” or “substantially” is intended to have meanings close to numerical values or ranges specified with an allowable error and intended to prevent accurate or absolute numerical values disclosed for understanding of the present disclosure from being illegally or unfairly used by any unconscionable third party. Through the whole document, the term “step of” does not mean “step for”.

Through the whole document, the term “combination of” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

Through the whole document, a phrase in the form “A and/or B” means “A or B, or A and B”.

Through the whole document, the term “alkyl group” typically refers to a linear or branched alkyl group having 1 to 24 carbon atoms, 1 to 20 carbon atoms, 1 to 10 carbon atoms, 1 to 8 carbon atoms, 1 to 5 carbon atoms, or 1 to 3 carbon atoms. If the alkyl group is substituted with an alkyl group, this may also be interchangeably used as “branched alkyl group”. A substituent which can substitute for the alkyl group may include at least one selected from the group consisting of halo (for example, F, Cl, Br, I), haloalkyl (for example, CCl₃ or CF₃), a lkoxy, a lkylthio, hydroxy, carboxy (—C(O)—OH), alkyloxy carbonyl (—C(O)—O—R), alkyl carbonyloxy (—O—C(O)—R), amino (—NH₂), carbamoyl (—NHC(O)OR— or —O—C(O)NHR—), urea (—NH—C(O)—NHR—), and thiol (—SH), but may not be limited thereto. Further, an alkyl group having two or more carbon atoms among the above-described alkyl groups may include at least one carbon-carbon double bond or at least one carbon-carbon triple bond, but may not be limited thereto. For example, the alkyl group may include methyl, ethyl, propyl, butyl, pentyl, hexyl, heptyl, octyl, nonyl, decyl, undecyl, dodecyl, tridecyl, tetradecyl, pentadecyl, hexadecyl, heptadecyl, octadecyl, nonadecyl, acosanyl, or all the possible isomers thereof, but may not be limited thereto.

Through the whole document, the term “halogen” or “halo” refers to a halogen atom from Group XVII of the periodic table included as a functional group in a compound, and may include, for example, chlorine, bromine, fluorine, or iodine, but may not be limited thereto.

Hereinafter, a method of fabricating a perovskite solar cell and a perovskite solar cell fabricated by the fabrication method according to the present disclosure will be described in detail with reference to the following embodiments and examples and the accompanying drawings. However, the present disclosure may not be limited to the following embodiments, examples, and drawings.

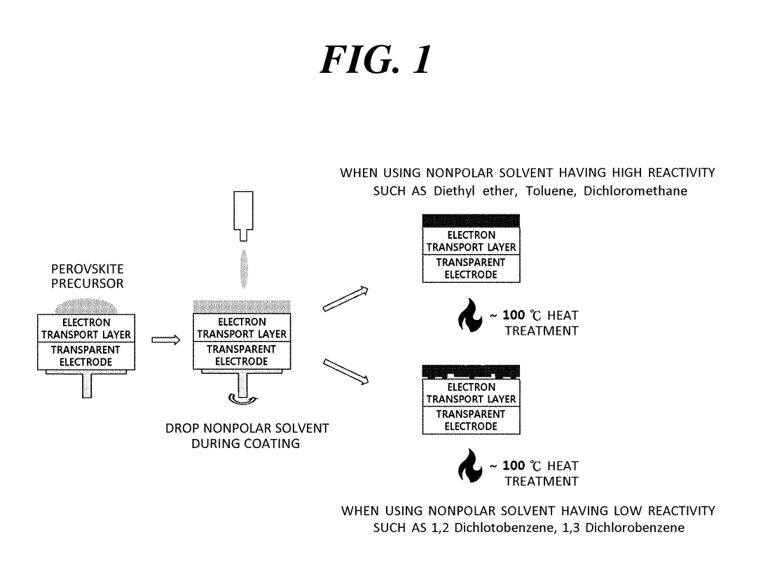

According to a conventional method of fabricating a perovskite solar cell, a conventional spin coating process in which a nonpolar solvent is dropped to form a mesophase of a perovskite light absorbing layer and a heat treatment is performed to form a thin film can form a uniform perovskite light absorbing layer in a small-scale process. However, in the case where the conventional spin coating process is applied to a large-area process, as the size of a substrate is increased, a thin film having a non-uniform thickness is coated on the substrate. Further, referring to FIG. 1, the conventionally used nonpolar solvents such as toluene and chlorobenzene have a property of dissolving dimethyl sulfoxide (DMSO) and are highly reactive. Therefore, when applied to a bath process, such a nonpolar solvent cannot uniformly form a perovskite mesophase containing DMSO.

Accordingly, there is a need for the development of a method of fabricating a perovskite solar cell in which a mesophase of a perovskite light absorbing layer can be uniformly formed regardless of the size of a substrate.

According to a first aspect of the present disclosure, there is provided a method of fabricating a perovskite solar cell, including: forming an electron transport layer on a substrate; forming a light absorbing layer containing a perovskite material on the electron transport layer; forming a hole transport layer on the light absorbing layer; and forming an electrode on the hole transport layer. Herein, the forming of the light absorbing layer is performed by impregnating the substrate on which the electron transport layer is formed in a nonpolar solvent and performing a heat treatment thereto.

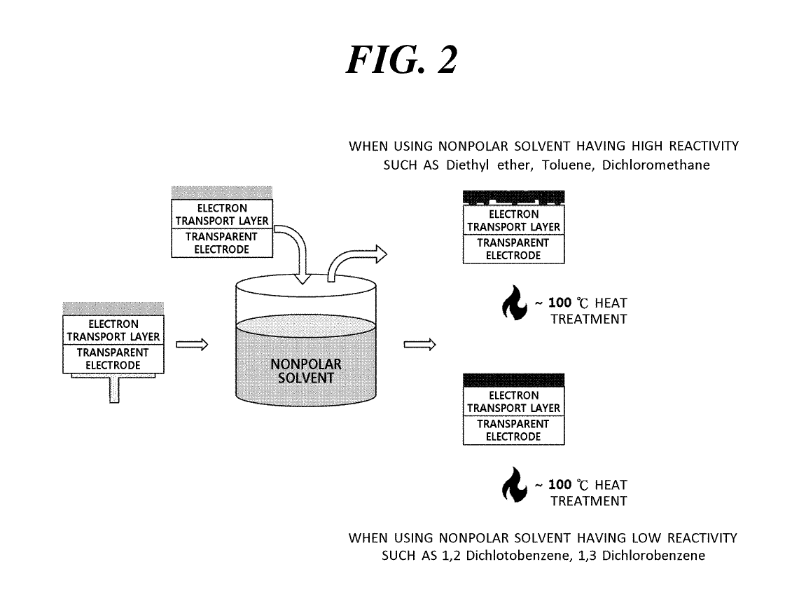

The nonpolar solvent has low reactivity, and according to the method of fabricating a perovskite solar cell of the present disclosure with reference to FIG. 2, a substrate including a mesophase of a perovskite light absorbing layer is impregnated in the nonpolar solvent having low reactivity and heat-treated. Thus, the mesophase of the perovskite light absorbing layer can be formed to a uniform thickness. Meanwhile, in the case where a substrate including a mesophase of a perovskite light absorbing layer is impregnated in a nonpolar solvent having high reactivity and heat-treated, the mesophase of the perovskite light absorbing layer may be non-uniformly formed.

More specifically, the nonpolar solvent may be a solvent which is affected by van der Waals force and has a vapor pressure of 20 mmHg or less at room temperature (25° C.), but may not be limited thereto.

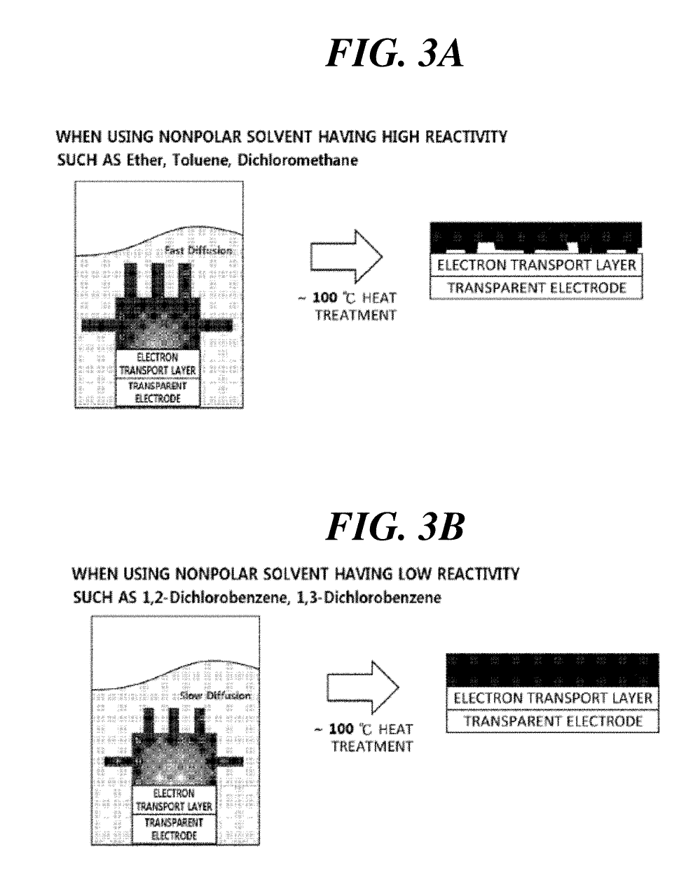

Further, referring to FIG. 3A-FIG. 3B, when the substrate impregnated in a nonpolar solvent having high reactivity, DMF or DMSO is rapidly washed, and, thus, crystals are rapidly formed. Therefore, a non-uniform thin film can be formed. However, when the substrate is impregnated in a nonpolar solvent having low reactivity according to the present disclosure, DMF or DMSO is slowly washed, and, thus, crystals are slowly formed. Therefore, a uniform perovskite mesophase can be formed.

According to an embodiment of the present disclosure, the nonpolar solvent having low reactivity may use any nonpolar solvent without limitation as long as it can slowly dissolve DMSO contained in the perovskite light absorbing layer. Desirably, the nonpolar solvent having low reactivity may be selected from the group consisting of chlorobenzene, 1,2-dichlorobenzene, 1,3-dichlorobenzene, chloronaphthalene, and mixed solvents thereof, but may not be limited thereto.

According to an embodiment of the present disclosure, the heat treatment may be performed at from 100° C. to 200° C., but may not be limited thereto.

If the heat treatment is performed at a temperature of less than 100° C. out of the above range, all of DMSO contained in the perovskite light absorbing layer cannot be evaporated or requires a long time to be evaporated. If the heat treatment is performed at a temperature of more than 200° C. out of the above range, the perovskite may be decomposed.

According to an embodiment of the present disclosure, the electron transport layer may include a porous metal oxide particle layer, but may not be limited thereto. For example, the electron transport layer may include an organic semiconductor, an inorganic semiconductor, or a mixture thereof, but may not be limited thereto.

According to an embodiment of the present disclosure, the electron transport layer may include an oxide of a metal selected from the group consisting of titanium, tin, zinc, tungsten, zirconium, gallium, indium, yttrium, niobium, tantalum, vanadium, and combinations thereof, but may not be limited thereto.

For example, the oxide of the metal may be selected from the group consisting of titanium dioxide (TiO₂), tin oxide (SnO₂), titanium (II) chloride (TiCl₂), zinc oxide (ZnO), copper (II) oxide (CuO), nickel (II) oxide (NiO), cobalt (II) oxide (CoO), indium oxide (In₂O₃), tungsten oxide (WO₃), magnesium oxide (MgO), calcium oxide (CaO), lanthanum oxide (La₂O₃), neodymium oxide (Nd₂O₃), yttrium oxide (Y₂O₃), cerium oxide (CeO₂), lead oxide (PbO), zirconium oxide (ZrO₂), iron oxide (Fe₂O₃), bismuth oxide (Bi₂O₃), vanadium pentoxide (V₂O₅), vanadium oxide (VO₂), niobium pentoxide (Nb₂O₅), cobalt(II,III) oxide (CO₃O₄), aluminum oxide (Al₂O₃), and combinations thereof, but may not be limited thereto.

According to an embodiment of the present disclosure, the perovskite material may include a compound represented by the following Chemical Formula 1, but may not be limited thereto.

RMX₃ [Chemical Formula 1]

In Chemical Formula 1, R includes an organic cation or an alkaline metal cation, or a mixed cation of the organic cation and the alkaline metal cation, M includes a metal cation selected from the group consisting of Cu²⁺, Ni²⁺, Co₂₊, Fe²⁺, Mn²⁺, Cr²⁺, Pd²⁺, Cd²⁺, Yb²⁺, Pb²⁺, Sn²⁺, Ge²⁺, and combinations thereof, and X is an anion.

According to an embodiment of the present disclosure, in Chemical Formula 1, R is a monovalent organic ammonium ion represented by (R¹R²R³R⁴N)⁺, and R¹ to R⁴ may include, each independently, a linear or branched alkyl group having 1 to 24 carbon atoms, a cycloalkyl group having 3 to 20 carbon atoms, an aryl group having 6 to 20 carbon atoms, and combinations thereof, but may not be limited thereto.

According to an embodiment of the present disclosure, in Chemical Formula 1, R may be a monovalent organic ammonium ion represented by (R⁵—NH₃)⁺, and R⁵ may include a member selected from the group consisting of a linear or branched alkyl group having 1 to 24 carbon atoms, a cycloalkyl group having 3 to 20 carbon atoms, an aryl group having 6 to 20 carbon atoms, and combinations thereof, but may not be limited thereto. For example, if R in Chemical Formula 1 is (R⁵—NH₃)⁺, R⁵ may be a methyl group or an ethyl group. For example, if R⁵ is a methyl group, R in Chemical Formula 1 may be a methyl ammonium (MA) ion represented by (CH₃NH₃)⁺, but may not be limited thereto.

According to an embodiment of the present disclosure, R in Chemical Formula 1 may be represented by a chemical formula (R⁶R⁷N═CH—NR⁸R⁹)⁺. Herein, R⁶ may be hydrogen, an unsubstituted or substituted alkyl group having 1 to 20 carbon atoms, or an unsubstituted or substituted aryl group, R⁷ may be hydrogen, an unsubstituted or substituted alkyl group having 1 to 20 carbon atoms, or an unsubstituted or substituted aryl group; R⁸ may be hydrogen, an unsubstituted or substituted alkyl group having 1 to 20 carbon atoms, or an unsubstituted or substituted aryl group; and R⁹ may be hydrogen, an unsubstituted or substituted alkyl group having 1 to 20 carbon atoms, or an unsubstituted or substituted aryl group, but may not be limited thereto. For example, in the cation (R⁶R⁷N═CH—CH—NR⁸R⁹)⁺, R⁶ may be hydrogen, a methyl group, or an ethyl group, R⁷ may be hydrogen, a methyl group, or an ethyl group, R⁸ may be hydrogen, a methyl group, or an ethyl group, and R⁹ may be hydrogen, a methyl group, or an ethyl group, but may not be limited thereto. For example, R⁶ may be hydrogen or a methyl group, R⁷ may be hydrogen or a methyl group, R⁸ may be hydrogen or a methyl group, and R⁹ may be hydrogen or a methyl group, but may not be limited thereto. For example, in Chemical Formula 1, R may be an organic cation represented by a chemical formula (R⁶R⁷N═CH—NR⁸R⁹)⁺ and specifically may have a chemical formula (H₂N═CH—NH₂)⁺, but may not be limited thereto.

If the alkyl group is substituted, a substituent may include, but not limited to, one or more members selected from the following group: a substituted or unsubstituted alkyl group having 1 to 20 carbon atoms, a substituted or unsubstituted aryl group, a cyano group, an amino group, an alkylamino group having 1 to 10 carbon atoms, a dialkylamino group having 1 to 10 carbon atoms, an arylamino group, a diarylamino group, an arylalkylamino group, an amido group, an acylamido group, a hydroxy group, an oxo group, a halo group, a carboxy group, an ester group, an acyl group, an acyloxy group, an alkoxy group having 1 to 20 carbon atoms, an aryloxy group, a haloalkyl group, a sulfonic acid group, a sulfhydryl group (i.e., thiol (—SH)), an alkylthio group having 1 to 10 carbon atoms, an arylthio group, a sulfonyl group, a phosphoric acid group, a phosphateester group, a phosphonic acid group, and a phosphonateester group. For example, the substituted alkyl group may include a halogen alkyl group, a hydroxyalkyl group, an aminoalkyl group, an alkoxyalkyl group, or an alkaryl group, but may not be limited thereto. The alkaryl group belongs to a substituted alkyl group having 1 to 20 carbon atoms and substituted with an aryl group for at least one hydrogen atom. For example, the aryl group substituted for at least one hydrogen atom may include a benzyl group (phenylmethyl (PhCH₂—)), a benzhydryl group (Ph₂CH—), a trityl group (triphenylmethyl (Ph₃C—)), a phenethyl group (phenylethyl (Ph—CH₂CH₂—)), a styryl group (PhCH═CH—), or a cinnamyl group (PhCH═CHCH₂—), but may not be limited thereto.

For example, if the alkyl group is substituted, there may be one, two, or three substituents for the alkyl group, but the present disclosure may not be limited thereto.

The aryl group used herein is a substituted or unsubstituted monocyclic or bicyclic aromatic group, and this group may include 6 to 14 carbon atoms and desirably 6 to 10 carbon atoms in the ring portion. For example, the aryl group used herein may include a phenyl group, a naphthyl group, an indenyl group, and an indanyl group, but may not be limited thereto. The aryl group may or may not be substituted. If the above-defined aryl group is substituted, a substituent may include, but not limited to, one or more members selected from the following group: an unsubstituted alkyl group having 1 to 6 carbon atoms (forming an aralkyl group), an unsubstituted aryl group, a cyano group, an amino group, an alkylamino group having 1 to 10 carbon atoms, a dialkylamino group having 1 to 10 carbon atoms, an arylamino group, a diarylamino group, an arylalkylamino group, an amido group, an acylamido group, a hydroxy group, a halo group, a carboxy group, an ester group, an acyl group, an acyloxy group, an alkoxy group having 1 to 20 carbon atoms, an aryloxy group, a haloalkyl group, a sulfhydryl group (i.e., thiol (—SH)), an a lkylthio group having 1 to 10 carbon atoms, an arylthio group, a sulfonic acid group, a phosphoric acid group, a phosphateester group, a phosphonic acid group, and a sulfonyl group. For example, the substituted aryl group may have one, two, or three substituents, but may not be limited thereto. For example, the substituted aryl group may be substituted at two positions together with a single alkylene group having 1 to 6 carbon atoms or a bidentate group represented by a chemical formula (—X—(C1-C6)alkylene) or a chemical formula (—X—(C1-C6)alkylene —X—). Herein, X may be selected from O, S, and NR and R may be H, an aryl group, or an alkyl group having 1 to 6 carbon atoms.

For example, the substituted aryl group may be an aryl group fused with a cycloalkyl group or a heterocyclyl group. For example, the ring atoms of an aryl group may include one or more heteroatoms as in a heteroaryl group. Such an aryl group or a heteroaryl group is a substituted or unsubstituted mono- or bicyclic heteroaromatic group and may contain from 6 to 10 atoms in the ring portion including one or more heteroatoms. For example, it may be a 5- or 6-membered ring, containing at least one heteroatom selected from O, S, N, P, Se and Si. For example, it may contain 1, 2, or 3 heteroatoms. For example, the heteroaryl group may include a pyridyl group, a pyrazinyl group, a pyrimidinyl group, a pyridazinyl group, a furanyl group, a thienyl group, a pyrazolidinyl group, a pyrrolyl group, an oxazolyl group, an oxadiazolyl group, an isoxazolyl group, a thiadiazolyl group, a thiazolyl group, an isothiazolyl group, an imidazolyl group, a pyrazolyl group, a quinolyl group, and an isoquinolyl group, but may not be limited thereto. For example, the heteroaryl group may not be substituted, or may be substituted as described above in connection with the aryl group. In the case where the heteroaryl group is substituted, the substituted heteroaryl group may have one, two, or three substituents, but may not be limited thereto.

In an embodiment of the present disclosure, in Chemical Formula 1, R may include an alkaline metal cation in addition to the organic cation, i.e., a mixed cation of the organic cation and the alkaline metal cation, but may not be limited thereto. In this case, a molar ratio of alkaline metal cations among all the cations of R in Chemical Formula 1 may be greater than 0 to 0.2, but may not be limited thereto. The alkaline metal cations may include cations of a metal selected from the group consisting of Cs, K, Rb, Mg, Ca, Sr, Ba, and combinations thereof, but may not be limited thereto.

According to an embodiment of the present disclosure, in Chemical Formula 1, X may include a halide anion or a chalcogenide anion, but may not be limited thereto. For example, in Chemical Formula 1, X may include one or more kinds of anions, and may include, for example, one or more kinds of halide anions, one or more kinds of chalcogenide anions, or mixed anions thereof. For example, in Chemical Formula 1, X may include a member selected from the group consisting of F⁻, Cl⁻, Br−, I⁻, S²⁻, Se²⁻, Te²⁻, and combinations t hereof, but may not be limited thereto. For example, in Chemical Formula 1, X may include one or more kinds of anions selected from the group consisting of F⁻, Cl⁻, Br⁻, I⁻, and combinations thereof as a monovalent halide anion, but may not be limited thereto. For example, in Chemical Formula 1, X may include a member selected from the group consisting of S²⁻, Se²⁻, Te²⁻, and combinations thereof as a divalent chalcogenide anion, but may not be limited thereto.

In an embodiment of the present disclosure, the perovskite compound in Chemical Formula 1 may include one or more members selected from CH₃NH₃PbIₓCl_{y} (x and y are real numbers satisfying 0≤x≤3, 0≤y≤3 and x+y=3), CH₃N H₃PbIₓBr_{y} (x and y are real numbers satisfying 0≤x≤3, 0≤y≤3, and x+y=3), CH₃NH₃PbClₓBr_{y} (x and y are real numbers satisfying 0≤x≤3, 0≤y≤3, and x+y=3), and CH₃NH₃PbIₓF_{y} (x and y are real numbers satisfying 0≤x≤3, 0≤y≤3, and x+y=3), and may include one or more members selected from (CH₃NH₃)₂PbIₓCl_{y} (x and y are real numbers satisfying 0≤x≤4, 0≤y≤4, and x+y=4), (CH₃NH₃)₂PbIₓBr_{y} (x and y are real numbers satisfying 0≤x≤4, 0≤y≤3, and x+y=4), (CH₃NH₃)₂PbClₓBr_{y} (x and y are real numbers satisfying 0≤x≤4, 0≤y≤3, and x+y=4), (CH₃NH₃)₂PbIₓF_{y} (x and y are real numbers satisfying 0≤x≤4, 0≤y≤4, and x+y=4), but may not be limited thereto.

In an embodiment of the present disclosure, the perovskite compound in Chemical Formula 1 may include one or more perovskite compounds selected from CH₃NH₃PbI₃, CH₃NH₃PbBr₃, CH₃NH₃PbCl₃, CH₃NH₃PbF₃, CH₃NH₃PbBrI₂, CH₃NH₃PbBrCl₂, CH₃NH₃PbIBr₂, CH₃NH₃PbICl₂, CH₃NH₃PbClBr₂, CH₃NH₃Pb1₂Cl, CH₃NH₃SnBrI₂, CH₃NH₃SnBrCl₂, CH₃NH₃SnF₂Br, CH₃NH₃SnlBr₂, CH₃NH₃SnICl₂, CH₃NH₃SnF₂I, CH₃NH₃SnClBr₂, CH₃NH₃SnI₂Cl, and CH₃NH₃SnF₂Cl, but may not be limited thereto.

For example, the perovskite compound in Chemical Formula 1 may include one or more perovskite compounds selected from CH₃NH₃PbBrI₂, CH₃NH₃PbBrCl₂, CH₃NH₃PbIBr₂, CH₃NH₃PbICl₂, CH₃NH₃PbClBr₂, CH₃NH₃PbI₂Cl, CH₃NH₃SnBrI₂, CH₃NH₃SnBrCl₂, CH₃NH₃SnF₂Br, CH₃NH₃SnIBr₂, CH₃NH₃SnICl₂, CH₃NH₃SnF₂I, CH₃NH₃SnClBr₂, CH₃NH₃SnI₂Cl, and CH₃NH₃SnF₂Cl, but may not be limited thereto.

For example, the perovskite compound in Chemical Formula 1 may include one or more perovskite compounds selected from CH₃NH₃PbBrI₂, CH₃NH₃PbBrCl₂, CH₃NH₃PbIBr₂, CH₃NH₃PbICl₂, CH₃NH₃PbClBr₂, CH₃NH₃PbI₂Cl, CH₃NH₃SnF₂Br, CH₃NH₃SnICl₂, CH₃NH₃SnF₂I, CH₃NH₃SnI₂Cl, and CH₃NH₃SnF₂Cl, but may not be limited thereto.

For example, the perovskite compound in Chemical Formula 1 may include one or more perovskite compounds selected from CH₃NH₃PbBrI₂, CH₃NH₃PbBrCl₂, CH₃NH₃PbIBr₂, CH₃NH₃PbICl₂, CH₃NH₃PbClBr₂, CH₃NH₃PbI₂Cl, CH₃NH₃SnF₂Br, CH₃NH₃SnF₂I, and CH₃NH₃SnF₂Cl, but may not be limited thereto.

For example, the perovskite compound in Chemical Formula 1 may include one or more perovskite compounds selected from CH₃NH₃PbBrI₂, CH₃NH₃PbBrCl₂, CH₃NH₃PbIBr₂, CH₃NH₃PbICl₂, CH₃NH₃SnF₂Br, and CH₃NH₃SnF₂I, but may not be limited thereto.

For example, the perovskite compound included in the perovskite solar cell according to an embodiment of the present disclosure may be methylammonium lead iodide (CH₃NH₃PbI₃; hereinafter, referred to as “MAPbl₃”), but may not be limited thereto. If MAPbl₃ is applied as the perovskite compound, it can be applied to a thin film p-i-n or p-n junction structure due to its balanced charge transport and a resultant micron-scale diffusion length, but may not be limited thereto.

According to an embodiment of the present disclosure, the perovskite compound may be used as dissolved in a polar aprotic solvent, but may not be limited thereto.

According to an embodiment of the present disclosure, the polar aprotic solvent may be selected from the group consisting of dimethylformamide (DMF), dimethylacetamide (DMA), N-methyl-2-pyrrolidone (NMP), dimethyl sulfoxide (DMSO), and combinations thereof, but may not be limited thereto.

According to an embodiment of the present disclosure, the hole transport layer may contain a monomer hole transport material or a polymer hole transport material, but may not be limited thereto.

For example, the monomer hole transport material may employ 2,2′,7,7′-tetrakis(diphenylamino)-9,9′-spirobifluorene (Spiro-MeOTAD) may be used and the polymer hole transport material may employ poly-hexylthiophene (P3HT), polytriarylamine (PTAA), poly(3,4-ethylenedioxythiophene), or polystyrene sulfonate (PEDOT:PSS), but may not be limited thereto. Besides, the polymer hole transport material may employ one member selected from the group consisting of 4-tert-butylpyridine (tBP), bis(trifluoromethane)sulfonimide lithium salt (Li-TFSI), poly[2-methoxy-5-(2-ethylhexyloxy)-1,4-phenylenevinylene] (MEHPPV), poly[2,5-bis(2-decyl dodecyl)pyrrolo[3,4-c]pyrrole-1,4(2H,5H)-dione-(E)-1,2-di(2,2′-bithiophen-5-yl)ethene (PDPPDBTE), and combinations thereof, but may not be limited thereto.

Further, for example, the hole transport layer may use a dopant selected from the group consisting of a Li-based dopant, a Co-based dopant, and combinations thereof as a doping material, but may not be limited thereto. For example, the hole transport material may employ a mixed material of Spiro-MeOTAD, Li-TFSI, and tBP, but may not be limited thereto.

According to an embodiment of the present disclosure, the transparent conductive substrate may include a glass substrate or plastic substrate containing a material selected from the group consisting of indium tin oxide (ITO), fluorine tin oxide (FTO), ZnO—Ga₂O₃, ZnO—Al₂O₃, tin-based oxide, zinc oxide, and combinations thereof, but may not be limited thereto. The transparent conductive substrate may use a material without particular limitation as long as the material has conductivity and transparency. For example, the plastic substrate may contain a polymer selected from the group consisting of polyethyleneterephthalate, poly(ethylenenaphthalate), polycarbonate, polypropylene, polyimide, cellulose triacetate, and combinations thereof, but may not be limited thereto. For example, the transparent conductive substrate may be doped with a metal selected from the group consisting of Group III metals, such as Al, Ga, In and Ti, and combinations thereof, but may not be limited thereto.

According to an embodiment of the present disclosure, the electrode layer may contain a member selected from the group consisting of Pt, Au, Ni, Cu, Ag, In, Ru, Pd, Rh, Ir, Os, C, conductive polymers, and combinations thereof, but may not be limited thereto.

According to an embodiment of the present disclosure, the electrode layer may be formed to a thickness of from 30 nm to 100 nm on the hole transport layer.

If the electrode layer is formed to a thickness of less than 30 nm out of the above range, electrons may not be transported properly.

According to a second aspect of the present disclosure, there is provided a perovskite solar cell fabricated by the fabrication method according to the first aspect of the present disclosure. Detailed descriptions of the second aspect of the present disclosure, which overlap with those of the first aspect of the present disclosure, are omitted hereinafter, but the descriptions of the first aspect of the present disclosure may be identically applied to the second aspect of the present disclosure, even though they are omitted hereinafter.

Hereinafter, the present disclosure will be explained in more detail with reference to Examples. However, the following Examples are illustrative only but do not limit the present disclosure.

### EXAMPLE 1

### Fabrication of Perovskite Solar Cell

First, a hole blocking layer was formed on a transparent conductive substrate. More specifically, a solution prepared by dissolving titanium diisopropoxide bis(acetylacetonate (75 wt % in isopropanol)) in 1-butanol to a concentration of 0.15 M was spin-coated on the substrate and then heat-treated at 500° C. to form a hole blocking layer. Then, an electron transport layer containing metal oxide was formed to collect electrons. Specifically, TiO₂ particles were dispersed in 1-butanol to a concentration of 10 mg/ml. Then, the resultant solution was spin-coated on the transparent conductive substrate to form an electron transport layer. A UV/ozone process was performed to the substrate on which the hole blocking layer and the electron transport layer to form a hydrophilic group on a surface of the substrate. Thus, the invasiveness of the substrate was improved.

Further, a solution in which DMSO including CH₃NH₃I and PbI₂ dissolved at a volume ratio of 1:1 was dissolved in DMF (dimethylformamide) to a concentration of 55 w % was prepared to prepare a precursor solution MAPbl₃ (methylammonium lead iodide). The surface of the substrate was coated using the prepared solution by spin coating. Then, the substrate was impregnated in a nonpolar solvent 1,2-dichlorobenzene and taken out of the solvent and then heat-treated at 100° C.

Furthermore, Spiro-MeOTAD (72 mg), tBP (28.8 4), and Li-TFSI (17.6 μL) dissolved in acetonitrile were dissolved in 1 ml of chlorobenzene to prepare a hole transport solution. Then, the hole transport solution was coated on the surface of the substrate, followed by spin coating. Then, an electrode was formed by depositing gold to 50 nm or more (10⁻⁶ torr) to fabricate a perovskite solar cell.

### Comparative Example 1

In order to check how the method of impregnating a substrate in a nonpolar solvent having low reactivity which is the greatest feature of the present disclosure affects the formation of a perovskite light absorbing layer, a perovskite solar cell as a comparative example was fabricated. The perovskite solar cell was fabricated in the same manner as in Example 1 except that ether was used instead of 1,2-dichlorobenzene.

### Test Example 1

### Check for Effect of Solvent on Formation of Perovskite Light Absorbing Layer

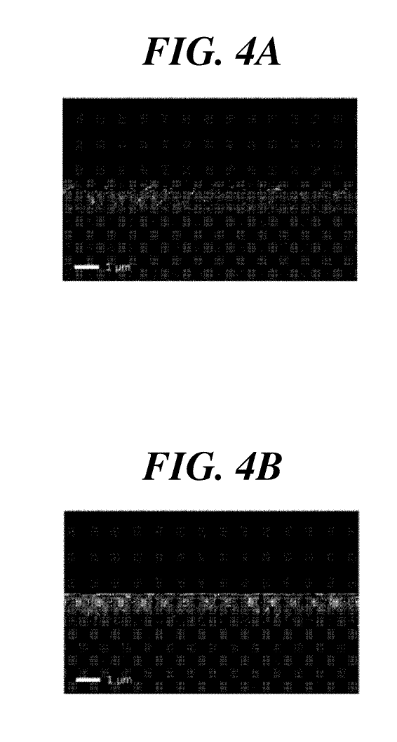

In order to check an effect of a solvent on the formation of a perovskite light absorbing layer, a light absorbing layer of the perovskite solar cell fabricated in Example 1 was compared with a light absorbing layer of the perovskite solar cell fabricated in Comparative Example 1. For comparison, the perovskite light absorbing layers of the respective perovskite solar cells were measured using a scanning electron microscope (SEM), and the result thereof was as shown in FIG. 4A-FIG. 4B.

As a result, it could be seen that in the case of using ether as a nonpolar solvent, the nonpolar solvent did not sufficiently react to a lower joint portion of the perovskite light absorbing layer, and, thus, the perovskite light absorbing layer was non-uniformly formed as shown in FIG. 4A. In contrast, it could be seen that in the case of using 1,2-dichlorobenzene as a nonpolar solvent according to the present disclosure, the nonpolar solvent sufficiently reacted to a lower joint portion of the perovskite light absorbing layer, and, thus, the perovskite light absorbing layer was uniformly formed.

### Test Example 2

### Check Photoelectric Conversion Efficiency

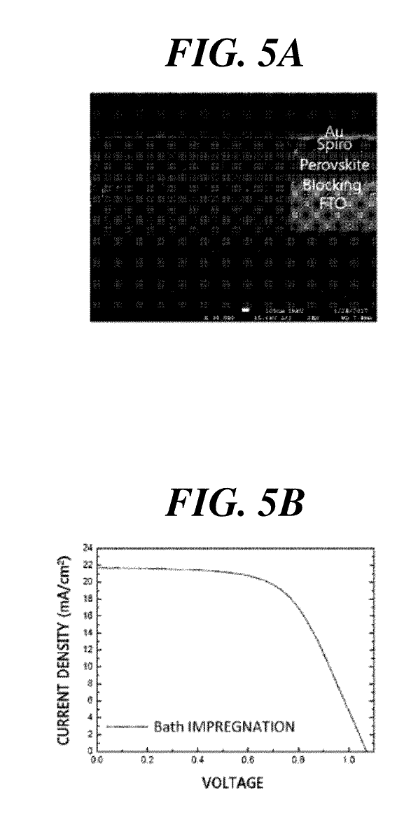

The perovskite solar cell fabricated in Example 1 was observed using an SEM. Further, a short circuit current density, an open circuit voltage, and a charge rate were checked from a J-V curve to check the efficiency of a device. As a result, it could be seen that the perovskite solar cell has a uniform perovskite light absorbing layer, as shown in FIG. 5A. Further, it could be seen from the J-V curve that the perovskite solar cell fabricated by the method of the present disclosure has an improved efficiency of a device compared with a perovskite solar cell fabricated by a conventional method, as shown in FIG. 5B.

The above description of the present disclosure is provided for the purpose of illustration, and it would be understood by those skilled in the art that various changes and modifications may be made without changing technical conception and essential features of the present disclosure.

Thus, it is clear that the above-described embodiments are illustrative in all aspects and do not limit the present disclosure. For example, each component described to be of a single type can be implemented in a distributed manner. Likewise, components described to be distributed can be implemented in a combined manner. The scope of the present disclosure is defined by the following claims rather than by the detailed description of the embodiment. It shall be understood that all modifications and embodiments conceived from the meaning and scope of the claims and their equivalents are included in the scope of the present disclosure.

1. A method of fabricating a perovskite solar cell, comprising:
forming an electron transport layer on a substrate;
forming a light absorbing layer containing a perovskite material on the electron transport layer;
forming a hole transport layer on the light absorbing layer; and
forming an electrode on the hole transport layer,
wherein the forming of the light absorbing layer is performed by impregnating the substrate on which the electron transport layer is formed in a nonpolar solvent and performing a heat treatment thereto.

2. The method of fabricating a perovskite solar cell of claim 1,
wherein the nonpolar solvent forms a perovskite mesophase.

3. The method of fabricating a perovskite solar cell of claim 1,
wherein the nonpolar solvent is selected from the group consisting of chlorobenzene, 1,2-dichlorobenzene, 1,3-dichlorobenzene, chloronaphthalene, and mixed solvents thereof.

4. The method of fabricating a perovskite solar cell of claim 1,
wherein the heat treatment may be performed at from 100° C. to 200° C.

5. The method of fabricating a perovskite solar cell of claim 1,
wherein the electron transport layer includes an oxide of a metal selected from the group consisting of titanium, tin, zinc, tungsten, zirconium, gallium, indium, yttrium, niobium, tantalum, vanadium, and combinations thereof.

6. The method of fabricating a perovskite solar cell of claim 5, wherein the oxide of the metal is selected from the group consisting of titanium dioxide (TiO2), tin oxide (SnO2), titanium (II) chloride (TiCl2), zinc oxide (ZnO), copper (II) oxide (CuO), nickel (II) oxide (NiO), cobalt (II) oxide (CoO), indium oxide (In2O3), tungsten oxide (WO3), magnesium oxide (MgO), calcium oxide (CaO), lanthanum oxide (La2O3), neodymium oxide (Nd2O3), yttrium oxide (Y2O3), cerium oxide (CeO2), lead oxide (PbO), zirconium oxide (ZrO2), iron oxide (Fe2O3), bismuth oxide (Bi2O3), vanadium pentoxide (V2O5), vanadium oxide (VO2), niobium pentoxide (Nb2O5), cobalt(II,III) oxide (Co3O4), aluminum oxide (Al2O3), and combinations thereof.

7. The method of fabricating a perovskite solar cell of claim 1,
wherein the perovskite material may include a compound represented by the following Chemical Formula 1:
RMX3 [Chemical Formula 1]
wherein in Chemical Formula 1, R includes an organic cation or an alkaline metal cation, or a mixed cation of the organic cation and the alkaline metal cation,
M includes a metal cation selected from the group consisting of Cu2+, Ni2+, Co2+, Fe2+, Mn2+, Cr2+, Pd2+, Cd2+, Yb2+, Pb2+, Sn2+, Ge2+, and combinations thereof, and
X is an anion.

8. The method of fabricating a perovskite solar cell of claim 7
wherein in Chemical Formula 1, R is a monovalent organic ammonium ion represented by (R1R2R3R4N)+, and R1 to R4 include, each independently, a linear or branched alkyl group having 1 to 24 carbon atoms, a cycloalkyl group having 3 to 20 carbon atoms, an aryl group having 6 to 20 carbon atoms, and combinations thereof.

9. The method of fabricating a perovskite solar cell of claim 7,
wherein in Chemical Formula 1, X includes a halide anion or a chalcogenide anion.

10. The method of fabricating a perovskite solar cell of claim 1,
wherein the hole transport layer contains a hole transport material selected from the group consisting of 2,2′,7,7′-tetrakis(diphenylamino)-9,9′-spirobifluorene (Spiro-MeOTAD), 4-tert-Butylpyridine (tBP), bis(trifluoromethane)sulfonimide lithium salt (Li-IFSI), poly-hexylthiophene (P3HT), poly[2-methoxy-5-(2-ethylhexyloxy)-1,4-phenylenevinylene] (MEHPPV), poly[2,5-bis(2-decyl dodecyl)pyrrolo[3,4-c]pyrrole-1,4(2H,5H)-dione-(E)-1,2-di(2,2′-bithiophen-5-yl)ethene (PDPPDBTE), and combinations thereof.

11. The method of fabricating a perovskite solar cell of claim 1,
wherein the substrate includes a glass substrate or plastic substrate containing a material selected from the group consisting of indium tin oxide (ITO), fluorine tin oxide (FTO), ZnO—Ga2O3, ZnO-Al2O3, tin-based oxide, zinc oxide, glass and combinations thereof.

12. The method of fabricating a perovskite solar cell of claim 11,
wherein the plastic substrate contains a polymer selected from the group consisting of polyethyleneterephthalate, poly(ethylenenaphthalate) (PEN), polycarbonate, polypropylene, polyimide, cellulose triacetate, and combinations thereof.

13. The method of fabricating a perovskite solar cell of claim 1,
wherein the electrode layer contains a member selected from the group consisting of Pt, Au, Ni, Cu, Ag, In, Ru, Pd, Rh, Ir, Os, C, conductive polymers, and combinations thereof.

14. The method of fabricating a perovskite solar cell of claim 13,
wherein the electrode layer is formed to a thickness of from 30 nm to 100 nm on the hole transport layer.

15. A perovskite solar cell fabricated by a method of claim 1.

16. A perovskite solar cell fabricated by a method of claim 14.
